(19) United States
(12) Patent Application Publication
(10) Pub. No.: US 2010/0128519 A1
(43) Pub. Date: May 27, 2010

(54) NON VOLATILE MEMORY HAVING INCREASED SENSING MARGIN

(75) Inventors: Hai Li, Eden Prairie, MN (US); Yiran Chen, Eden Prairie, MN (US); Xiaobin Wang, Chanhassen, MN (US); Yuan Yan, Edina, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/500,172

(22) Filed: Jul. 9, 2009

Related U.S. Application Data
(60) Provisional application No. 61/117,657, filed on Nov. 25, 2008.

(51) Int. Cl. G11C 11/14; G11C 7/02; G11C 7/06

(52) U.S. Cl. 365/171; 365/210.1; 365/189.07

(57) ABSTRACT

A non volatile memory assembly that includes a reference element having: a reference component; and a reference transistor, wherein the reference component is electrically connected to the reference transistor, and the reference transistor controls the passage of current across the reference component; and at least one non volatile memory element having: a non volatile memory cell, having at least a low and a high resistance state; and an output that electrically connects the reference element with the at least one non volatile memory element, wherein the reference transistor and the memory transistor are activated by a reference gate voltage and a memory gate voltage respectively, and the reference gate voltage and the memory gate voltage are not the same.

### PRIORITY

This application claims priority to U.S. Provisional Application No. 61/117,657 entitled “AN OPTIMIZED ST-RAM STRUCTURE WITH HIGH SENSING MARGIN” filed on Nov. 25, 2008, the disclosure of which is incorporated herein by reference.

### BACKGROUND

New types of memory have demonstrated significant potential to compete with commonly utilized types of memory. For example, non-volatile spin-transfer torque random access memory (referred to herein as “STRAM”) and resistive random access memory (referred to herein as “RRAM”) are both considered good candidates for the next generation of memory.

Typically, an STRAM cell includes a driving transistor and a magnetic tunnel junction (MTJ). The resistance of the MTJ changes based on whether the magnetic layers are oriented in parallel or in anti-parallel. The parallel orientation has a lower resistance than the anti-parallel resistance, and the MTJ can therefore store either a “1” or a “0”.

Reading the data in the STRAM cell involves determining the resistance state of the MTJ. This is generally accomplished by comparing a determined resistance with a reference resistance. The closer the two resistance states are to the reference resistance, the more likely mistakes can be made in the reading process. Therefore, increasing the margin between the resistance state and the reference resistance can increase the reliability of the STRAM cell for data storage and retrieval.

### BRIEF SUMMARY

A non volatile memory assembly that includes a reference element having: a reference component; and a reference transistor, wherein the reference resistor is electrically connected to the reference transistor, and the reference transistor controls the passage of current across the reference resistor; and at least one non volatile memory element having: a non volatile memory cell, having at least a low and a high resistance state; and an output that electrically connects the reference element with the at least one non volatile memory element, wherein the reference transistor and the memory transistor are activated by a reference gate voltage and a memory gate voltage respectively, and the reference gate voltage and the memory gate voltage are not the same.

A non volatile memory array that includes at least one reference element having: a reference resistor; and a reference transistor, wherein the reference resistor is electrically connected to the reference transistor, and the reference transistor controls the passage of current across the reference resistor; and a plurality of non volatile memory elements, each non volatile memory element having a non volatile memory cell, having at least a low and a high resistance state; and a memory transistor, wherein the non volatile memory cell is electrically connected to the memory transistor, and the memory transistor controls the passage of current across the non volatile memory cell, wherein the plurality of non volatile memory cells are arranged in a matrix of rows and columns, wherein a selected reference element is operatively coupled to a single column of non volatile memory cells, and wherein a selected reference transistor and a selected memory transistor are activated by a reference gate voltage and a memory gate voltage respectively, and the reference gate voltage and the memory gate voltage are not the same.

A method of determining the resistance state of a non volatile memory cell that includes the steps of: providing a non volatile memory element, the non volatile memory element having: a non volatile memory cell, having a high and low resistance state; and a memory transistor, wherein the transistor can be activated by application of a memory gate voltage; providing a reference cell, the reference cell having: a reference resistor; and a reference transistor, wherein the reference transistor can be activated by application of a reference gate voltage; activating the memory transistor by application of the memory gate voltage causing a current to pass across the non volatile memory cell; measuring a voltage across the non volatile memory cell; activating the reference transistor by application of a reference gate voltage causing a current to pass across the reference resistor; measuring a voltage across the reference resistor; and comparing the voltage across the non volatile memory cell to the voltage across the reference resistor to determine a resistance state of the non volatile memory cell, wherein the memory gate voltage and the reference gate voltage are independently chosen to maximize the difference between the resistance across the non volatile memory cell and the resistance across the reference resistor.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIGS. 1A, 1B and 1C are schematic diagrams of resistive sense memory (RSM) cells and more specifically, FIGS. 1A and 1B are STRAM cells and FIG. 1C is a RRAM cell.

FIGS. 2A and 2B are schematic diagrams of exemplary reference resistors;

FIG. 3 is a schematic diagram of a memory element within a larger system for reading and writing to the memory element;

FIG. 4 is a schematic diagram of a reference element and memory element as disclosed herein;

FIGS. 5A and 5B are graphs showing the sensing margin (ΔV) as a function of the ratio of the memory gate voltage (V_{GM}) over the supply voltage (V_{DD}) (FIG. 5A); and as a function of the ratio of the reference gate voltage (V_{GR}) over the supply voltage (V_{DD}) (FIG. 5B);

FIGS. 6A and 6B are schematic diagrams of a reference element configured within a memory assembly (FIG. 6A) and a memory array (FIG. 6B); and

FIGS. 7A and 7B are flowcharts depicting exemplary embodiments of methods disclosed herein.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Disclosed herein reference elements, non volatile memory elements, assemblies and arrays that include such elements, and methods of determining the resistance of the non volatile memory elements that provide an increased sensing margin. A non volatile memory element generally includes a non volatile memory cell and an associated transistor.

A non volatile memory cell utilized herein can include many different types of memory. Exemplary types of memory that can be utilized in devices disclosed herein include, but are not limited to non volatile memory such as, resistive sense memory (RSM) cells. A RSM cell is a memory cell having a changeable resistance that affords data storage using different resistance states of the RSM cell. Exemplary RSM cells include, but are not limited to, ferroelectric RAM (FeRAM or FRAM); magnetoresistive RAM (MRAM); resistive RAM (RRAM); phase change memory (PCM) which is also referred to as PRAM, PCRAM and C-RAM; programmable metallization cell (PMC) which is also referred to as conductive-bridging RAM or CBRAM; and spin torque transfer RAM, which is also referred to as STRAM.

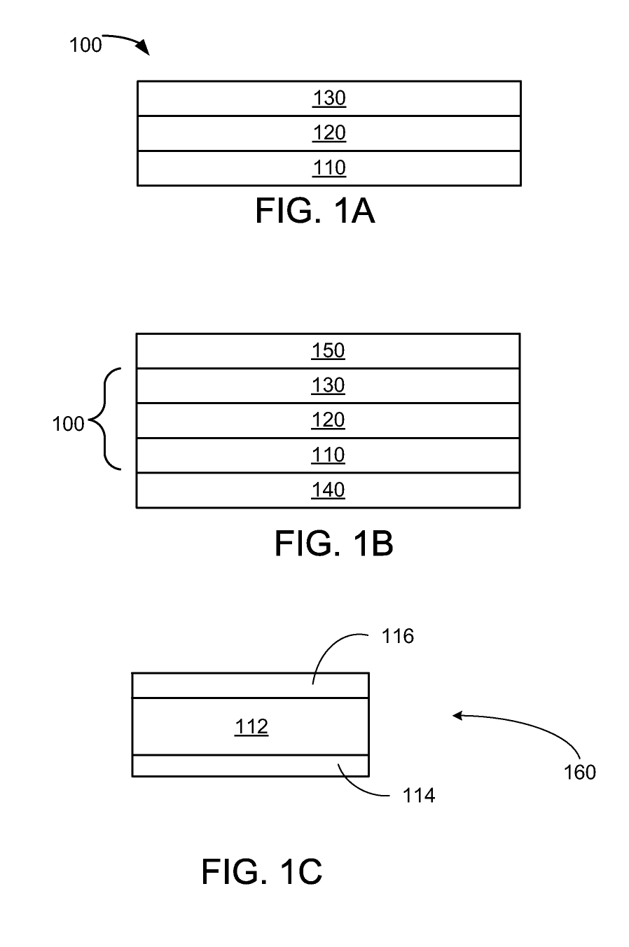

In embodiments, the RSM cell can be a STRAM cell. STRAM memory cells include a MTJ (magnetic tunnel junction), which generally includes two magnetic electrode layers separated by a thin insulating layer, which is also known as a tunnel barrier. An embodiment of a MTJ is depicted in FIG. 1A. The MTJ 100 in FIG. 1A includes a first magnetic layer 110 and a second magnetic layer 130, which are separated by an insulating layer 120. FIG. 1B depicts a MTJ 100 in contact with a first electrode layer 140 and a second electrode layer 150. The first electrode layer 140 and the second electrode layer 150 electrically connect the first magnetic layer 110 and the second magnetic layer 130 respectively to a control circuit (not shown) providing read and write currents through the magnetic layers. The relative orientation of the magnetization vectors of the first magnetic layer 110 and the second magnetic layer 130 can be determined by the resistance across the MTJ 100; and the resistance across the MTJ 100 can be determined by the relative orientation of the magnetization vectors of the first magnetic layer 110 and the second magnetic layer 130.

The first magnetic layer 110 and the second magnetic layer 130 are generally made of ferromagnetic alloys such as iron (Fe), cobalt (Co), and nickel (Ni) alloys. In embodiments, the first magnetic layer 110 and the second magnetic layer 130 can be made of alloys such as FeMn, NiO, IrMn, PtPdMn, NiMn and TbCo. The insulating layer 120 is generally made of an insulating material such as aluminum oxide (Al₂O₃) or magnesium oxide (MgO).

The magnetization of one of the magnetic layers, for example the first magnetic layer 110 is generally pinned in a predetermined direction, while the magnetization direction of the other magnetic layer, for example the second magnetic layer 130 is free to rotate under the influence of a spin torque. Pinning of the first magnetic layer 110 may be achieved through, e.g., the use of exchange bias with an antiferromagnetically ordered material such as PtMn, IrMn and others.

In embodiments, the RSM cell can be a RRAM cell. FIG. 1C is a schematic diagram of an illustrative resistive random access memory (RRAM) cell 160. The RRAM cell 160 includes a medium layer 112 that responds to an electrical current or voltage pulse by altering an electrical resistance of the medium layer 112. This phenomenon can be referred to as the electrical pulse induced resistance change effect. This effect changes the resistance (i.e., data state) of the memory from one or more high resistance state(s) to a low resistance state, for example. The medium layer 112 is interposed between a first electrode 114 and the second electrode 116 and acts as a data storage material layer of the RRAM cell. The first electrode 114 and the second electrode 116 are electrically connected to a voltage source (not shown). The first electrode 114 and a second electrode 116 can be formed of any useful electrically conducting material such as, for example, a metal.

The material forming the medium layer 112 can be any known useful RRAM material. In embodiments, the material forming the medium layer 112 can include an oxide material such as, a metal oxide. In some embodiments, the metal oxide is a binary oxide material or complex metal oxide material. In other embodiments, the material forming the medium layer 112 can include a chalcogenide solid electrolyte material or an organic/polymer material.

The binary metal oxide material can be expressed as a chemical formula of MₓO_{y}. In this formula, the characters “M”, “O”, “x”, and “y” refer to metal, oxygen, a metal composition ratio, and an oxygen composition ratio, respectively. The metal “M” may be a transition metal and/or aluminum (Al). In this case, the transition metal may be nickel (Ni), niobium (Nb), titanium (Ti), zirconium (Zr), hafnium (Hf), cobalt (Co), iron (Fe), copper (Cu) and/or chrome (Cr). Specific examples of binary metal oxides that may be used as the medium layer 112 include CuO, NiO, CoO, ZnO, CrO₂, TiO₂, HfO₂, ZrO₂, Fe₂O₃, and Nb₂O₅.

In embodiments, the metal oxide can be any useful complex metal oxide such as, for example, a complex oxide material having a formula Pr_{0.7}Ca_{0.3}MnO₃, or SrTiO₃, or SiZrO₃, or these oxides doped with Cr or Nb. The complex can also include LaCuO₄, or Bi₂Sr₂CaCu₂O₈. One example of a solid chalcogenide material is a germanium-selenide (GeₓSe₁₀₀₋ₓ) containing a silver (Ag) component. One example of an organic material is Poly(3,4-ethylenedioxythiophene) (i.e., PEDOT).

The RSM cell can also include ferroelectric capacitors having structures similar to FIG. 1C using materials such as lead zirconate titanate (referred to as “PZT”) or SrBi₂Ta₂O₉ (referred to as “SBT”). In such memory cells, an electrical current can be used to switch the polarization direction and the read current can detect whether the polarization is up or down. In such embodiments, a read operation is a destructive process, where the cell will lose the data contained therein, requiring a refresh to write data back to the cell.

Memory elements as disclosed herein also include transistors. Generally, field-effect transistors (FETs) are utilized. FETs generally have a gate, a drain, a source and a body (or substrate). The gate generally controls the opening and closing of the FET, similar to a physical gate. The gate permits electrons to flow through (when open) or blocks their passage (when closed) by creating or eliminating a channel between the source and the drain. Electrons flow from the source terminal towards the drain terminal when influenced by an applied voltage. The body or substrate is the bulk of the semiconductor in which the gate, source and drain lie.

In embodiments, memory elements as disclosed herein can utilize metal-oxide-semiconductor field-effect transistors (MOSFETs). MOSFETs are generally composed of a channel of n-type or p-type semiconductor material and are respectively referred to as NMOSFETs or PMOSFETs (also commonly referred to as “NMOS”, and “PMOS” transistors). Embodiments can also utilize complimentary metal-oxide-semiconductor transistors (“CMOS” transistors). The transistors in a memory element and a reference element can, but need not be the same kind of transistors.

Transistors, both the transistor coupled to the memory cell (referred to herein as a “memory transistor”) and the transistor coupled to the reference resistor (referred to herein as a “reference transistor”) allow different amounts of current to pass to its associated memory cell or reference resistor when different voltages are supplied to the gate of the transistor. Generally, the larger the voltage supplied to the gate of a transistor, the larger the current that passes through it.

In embodiments, either PMOS or NMOS transistors can be independently utilized as memory transistors and/or reference transistors. A NMOS transistor has a maximum source line voltage (Vₛ) of V_{DD}−I*R−Vₜ, where Vₜ is the threshold voltage of the NMOS transistor; and a PMOS transistor has a maximum source line voltage of V_{DD}−I*R. In embodiments, PMOS transistors can be utilized as the memory transistor, the reference transistor, or both because they can provide larger source line voltages. In embodiments, the reference transistor can be a PMOS transistor and the memory transistor can be a NMOS transistor. Use of a NMOS transistor as the memory transistor and a PMOS transistor for the reference transistor can also offer efficiencies of space because the memory cells, which there will be significant more of than reference cells will have the smaller NMOS transistors as opposed to PMOS transistors.

Also disclosed herein are reference elements. Reference elements are similar to memory elements in that they each include a transistor that is operably coupled to a resistive component. Transistors such as those discussed above with respect to memory elements can also be utilized in reference elements.

In a memory element, the resistive component is capable of storing data and is therefore a memory component or a memory cell. In a reference element, the reference component can be a resistive component referred to as a reference resistor. Generally, any resistive structure can be used as the reference resistor in a reference element disclosed herein. In embodiments, the resistance of the reference resistor can be between the resistance of the two states of the memory cell. In an embodiment where the memory cell is a STRAM cell, the resistance of the reference resistor can therefore be between the resistance of the parallel (R_{P}) or low state of the STRAM cell and the resistance of the anti-parallel (R_{AP}) or high state of the STRAM cell.

Exemplary structures that can be utilized as reference resistors can include structures that are similar or substantially the same as the non volatile memory cells in the memory element. For example, in an embodiment where the memory element includes a STRAM cell, the reference element can include a reference resistor that includes one or more MTJS. Such an embodiment may be advantageous because the same materials will be used for both the memory cell and the reference cell, this can allow the same processes to be utilized to fabricate the cells, which can therefore allow the systems to be manufactured more economically. In embodiments, the MTJs in the reference resistor can include the same materials as that in the non volatile memory cell but can be configured differently. In embodiments, the MTJs in the reference resistor can include materials that are different than those in the non volatile memory cells.

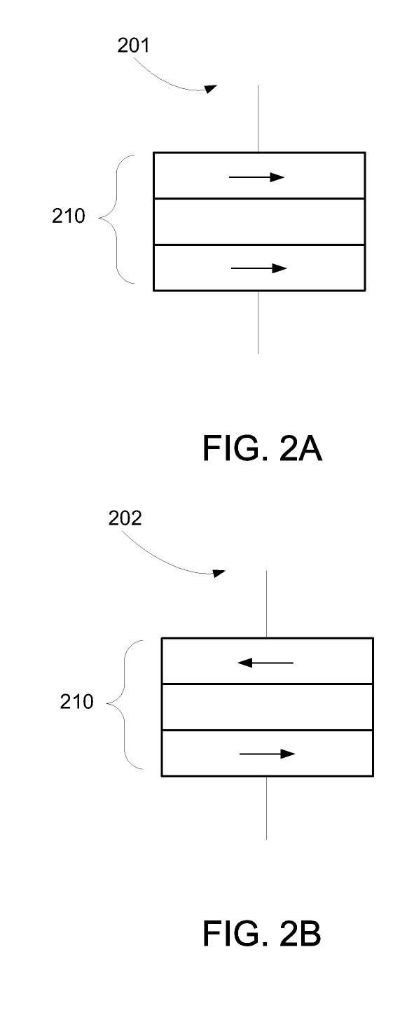

Specific exemplary embodiments of reference resistors are depicted in FIGS. 2A and 2B. The reference resistors depicted in FIGS. 2A and 2B each include a MTJ, MTJ 210 in FIG. 2A and MTJ 220 in FIG. 2B respectively. The properties, characteristics and materials of the MTJs 210 and 220 can be similar to those described and exemplified above with respect to the STRAM cells. In embodiments, MTJs in which both of the layers are pinned to the desired orientation (as opposed to the free layer, which is present in a STRAM cell so that the MTJ is rewriteable) can be utilized in reference resistors. As discussed above with respect to STRAM cells, a STRAM cell has two different resistance states, a parallel resistance state that exists when the pinned layer and the free layer have the same magnetic orientation and an anti-parallel resistance state that exists when the pinned layer and the free layer have opposite magnetic orientations. In embodiments, a reference resistor, such as that depicted in FIG. 2A, could include a MTJ 210 that is in a parallel configuration, as shown by the arrows designating the magnetic orientation of the two magnetic layers. In embodiments, a reference resistor, such as that depicted in FIG. 2B, could include a MTJ 220 that is in an anti-parallel configuration, as shown by the arrows designating the magnetic orientation of the two magnetic layers. The reference gate voltage of such a reference resistor (either including a parallel or an anti-parallel), and/or the memory gate voltage of its corresponding memory element(s) can be chosen so that the voltage from the reference element will be between the high and low resistance states of the memory element(s).

In embodiments, a reference component or reference resistor can also include more than one MTJ stack. In embodiments, a reference resistor can include a first MTJ stack having a parallel magnetic state and a second MTJ stack having an anti-parallel state. In such embodiments, the first and second MTJ stacks can be connected in parallel.

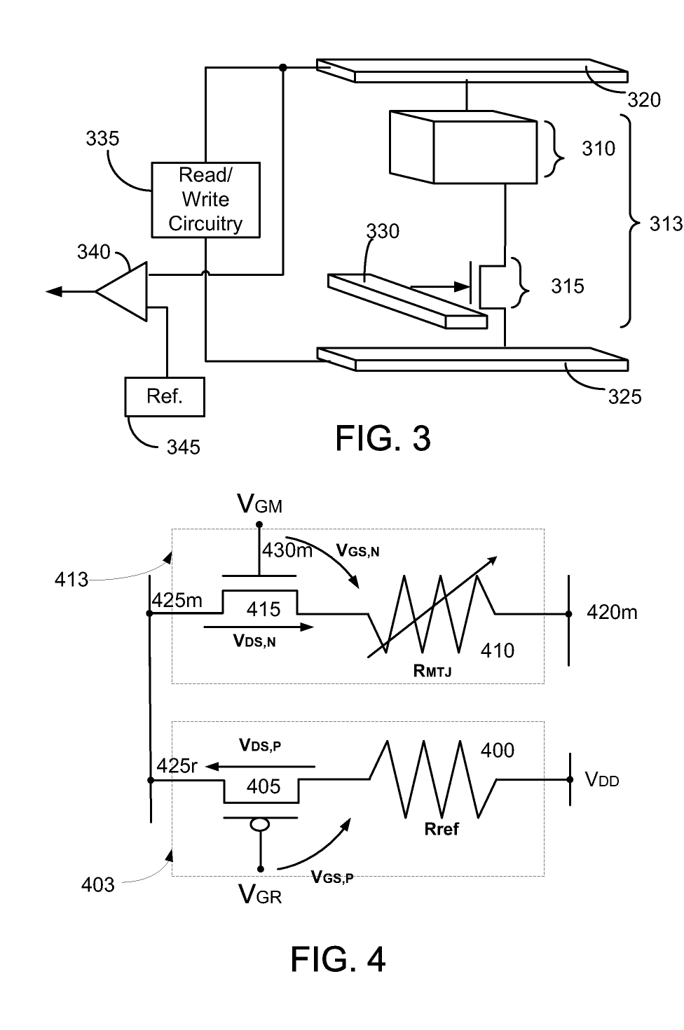

FIG. 3 illustrates a memory device that includes a memory element 313 that can include a memory cell 310 and its corresponding transistor 315. Single memory elements 313 can be configured within larger systems. The memory element 313 can be operatively coupled between a bit line 320 and a source line 325 within a larger system. The read/write circuitry 335 controls the particular bit line 320 and source line 325 that current passes through, thereby controlling the particular memory cell that is read from or written to. The read/write circuitry 335 can also control the voltage applied across the bit line 320 or memory element 313 from the source line 325 (or vice versa). The direction which current flows across a memory cell 310 is determined by the voltage differential across the bit line 320 and the source line 325.

A particular memory cell 310 can be read from by activating its corresponding transistor 315, which when turned on, allows current to flow from the bit line 320 through the memory cell 310 to the source line 325 (or vice versa). The transistor 315 is activated and deactivated through the word line 330. The word line 330 is operatively coupled to and supplies a voltage to the transistor 315 to turn the transistor on so that current can flow to the memory cell 310. A voltage, dependent on the resistance of the memory cell 310 is then detected by the sense amplifier 340 from the source line 325 (for example). The voltage differential between the bit line 320 and the source line 325 (or vice versa), which is indicative of the resistance of the memory cell 310 is then compared to a reference voltage 345 and amplified by the sense amplifier 340 to determine whether the memory cell 310 contains a “1” or a “0”.

As discussed above, a read operation determines the state (“1” or “0”) of the memory cell by comparing a voltage (that is indicative of the resistance of the memory cell) to a reference voltage (depicted as reference voltage 345 in FIG. 3). Methods may employ a reference voltage (Vref) that is directly between the voltage generated by the high resistance state of the memory cell and the low resistance state of the memory cell. This can be further explained by Equation I below:

$${V}_{Ref} = {I}_{Read} ( \frac{{R}_{AP} + {R}_{p}}{2} ) \qquad ( Equation I )$$

The sensing margin (ΔV), which can be explained as the difference in the voltage generated by the memory cell containing either a “0” or a “1”, can then be calculated by Equation II below.

$$Δ V = {V}_{AP} - {V}_{Ref} = {V}_{Ref} - {V}_{P} = {I}_{Read} ( \frac{{R}_{AP} + {R}_{p}}{2} ) \qquad ( Equation II )$$

This may lead to a sensing margin, ΔV, of less than about 50 mV in some embodiments (assuming that R_{AP}−R_{P}=1 KΩ; and I_{Read}=100 μA). A small sensing margin, such as less than about 50 mV, requires a complex sense amplifier (which requires significant on-chip area) and a long sensing time (which results in low speed memory) to resolve the signals.

In methods disclosed herein, the reference voltage is determined by passing a current across a reference resistor, measuring the voltage there from and comparing that with the voltage from the memory cell. The gate voltages for both the memory transistor and the reference transistor in such a method are chosen such that the voltages for V_{P}, V_{AP} and V_{Ref} create a larger sensing margin.

FIG. 4 depicts a reference element 403 and a memory element 413. A reference component or more specifically, a reference resistor 400 can be electrically connected to a reference transistor 405 to form a reference element 403. In some embodiments, the reference resistor 400 can be a reference memory cell. The reference element 403 can be operatively coupled between a supply voltage V_{DD} and an output 425r. The output 425r can be operatively coupled with the remaining circuitry of a larger system that allows the reference element to provide a reference voltage for determining the resistance of the memory element 413. The reference transistor 405 can be activated and deactivated by application of a gate voltage. The gate voltage can be operatively coupled to and supplies a voltage to the transistor 405 to turn the transistor on so that current can flow to the reference resistor 400. The voltage supplied to the gate of the reference transistor 405 can be referred to herein as the reference gate voltage, or V_{GR}.

Also included in FIG. 4 is a memory element 413. The components of memory element 413 are as discussed above. The memory cell 410 can be operatively coupled to a bit line 420m. The gate of the memory transistor 415 can be operatively coupled to a word line 430m. The word line 430m can supply the gate voltage to turn the memory transistor on. The voltage supplied to the gate of the memory transistor 415 can be referred to herein as the memory gate voltage, or V_{GM}. The source of the memory transistor 415 can be operatively coupled to a source line 425m. It should also be noted that the output 425r can be directly electrically connected to the source line 425m.

The resistance value of a memory cell (or a reference resistor); either the resistance of the parallel configuration (RP) or the resistance of the anti-parallel configuration (RAP) affects the source voltage of the transistor. Generally, the larger the resistance of the memory cell (or the reference resistor) the smaller the gate to source voltage (V_{GS}), and/or the drain to source voltage (V_{DS}). As an example, in embodiments where RAP≈2RP, even though the resistance is about half, when the memory cell switches from RP to RAP, the current is not actually reduced in half. So overall I*RAP>I*RP; and therefore as the resistance increases across the memory cell, the voltage across the memory cell increases, and therefore the voltage across the transistor decreases. This also results in a larger resistance of the transistor and a larger voltage at the bit line or source line (depending on the direction of the current flow).

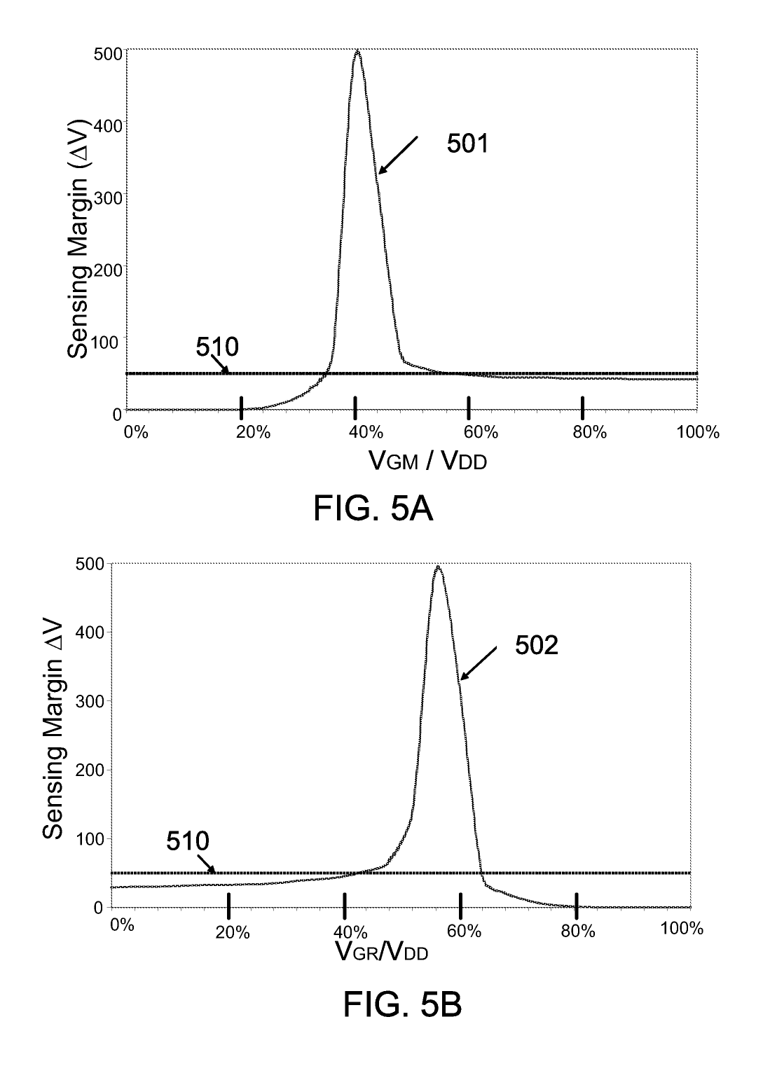

Based on the above, the gate voltages of the memory transistor (V_{GM}) and the reference transistor (V_{GR}) can be chosen to maximize the difference between the voltage of the reference element and both the low and high resistance states of the memory element, i.e. the sensing margin. FIG. 5A depicts the sensing margin of embodiments of the present invention 501 as a function of the ratio of the gate voltage of the memory transistor (V_{GM}) over the supply voltage (V_{DD}) while not altering the gate voltage of the reference element (and therefore the R_{ref}). In embodiments, the ratio of the gate voltage of the memory transistor (V_{GM}) over the supply voltage (V_{DD}) can be from about 35% to about 50%. In embodiments, the ratio of the gate voltage of the memory transistor (V_{GM}) over the supply voltage (V_{DD}) can be about 40%. In an embodiment where a memory element has a supply voltage of about 2.5 V, the gate voltage of the memory transistor can be about 1 V. Also seen in FIG. 5A, for comparison purposes is the sensing margin 510 for a commonly utilized reading scheme.

FIG. 5B depicts the sensing margin of embodiments of the present invention 502 as a function of the gate voltage of the reference element (V_{GR}) over the supply voltage (V_{DD}) while not altering the gate voltage of the memory element (and therefore R_{P} and R_{AP}). In embodiments, the ratio of the gate voltage of the reference transistor (V_{GR}) over the supply voltage (V_{DD}) can be from about 50% to about 65%. In embodiments, the ratio of the gate voltage of the reference transistor (V_{GR}) over the supply voltage (V_{DD}) can be about 60%. In an embodiment where a memory element has a supply voltage of about 2.5 V, the gate voltage of the memory transistor can be about 1.5 V. Also seen in FIG. 5B, for comparison purposes is the sensing margin 510 for a commonly utilized reading scheme.

In embodiments, both the gate voltages for the reference element and the memory element can be considered independently to increase the sensing margin.

Reference elements and memory elements as disclosed herein can be included in larger systems or assemblies. An exemplary assembly includes at least one reference element and at least one memory element. The at least one reference element and at least one memory element are electrically configured to allow the reference element to provide a reference voltage for use in determining the resistance state of the memory element. Exemplary assemblies can contain one reference element that is operably configured with more than one memory elements. Such a configuration can offer advantages in minimizing the overhead for the reference elements.

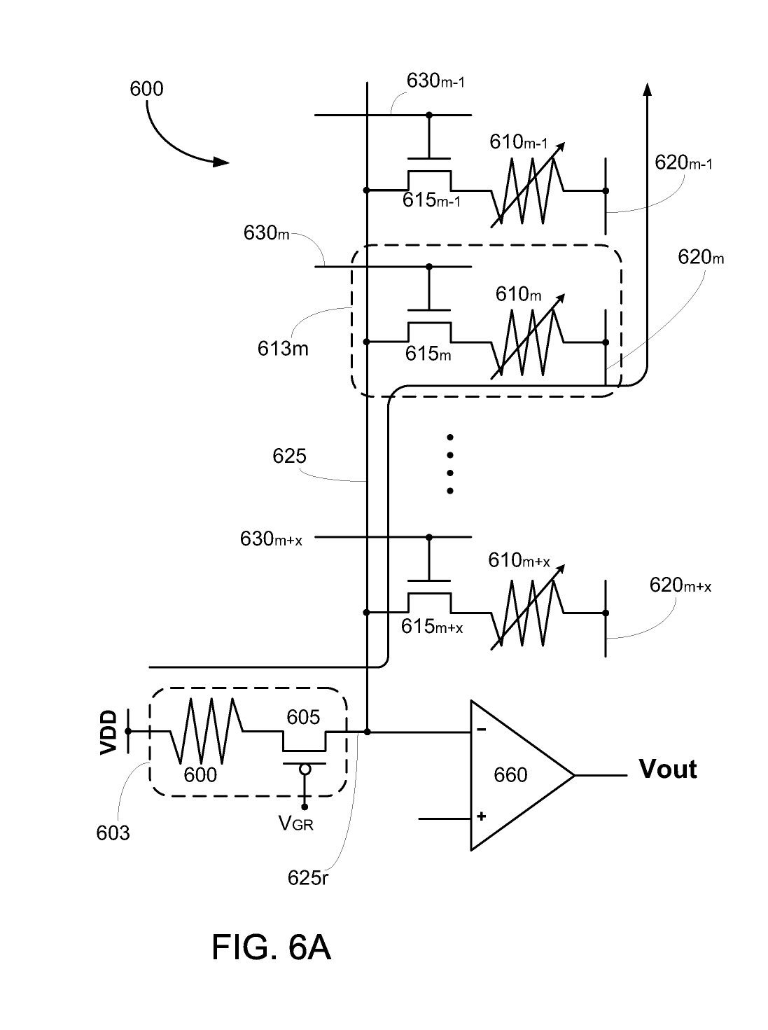

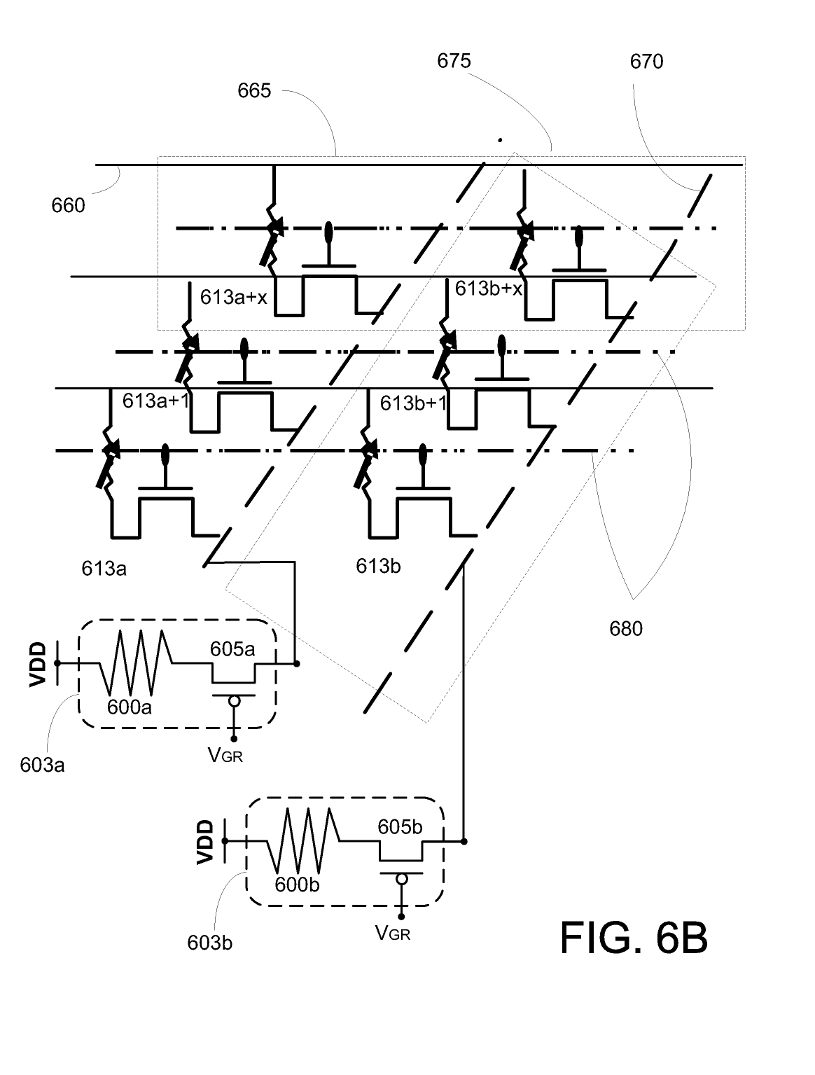

FIG. 6A depicts an exemplary memory assembly 600 that includes more than one memory element 613 and at least one reference element 603. In embodiments, the memory assembly can include a plurality of memory cells for each single reference element. Generally, a plurality refers to at least two and generally refers to more than two. As seen in FIG. 6A the memory element 613 can include a memory transistor 615m that is electrically coupled to a source line 625. The source line 625 can be electrically coupled to the other memory elements 613ₘ₋₁, 613ₘ₊ₓ depicted in the memory assembly 600. A group of memory elements that are electrically connected via a common source line (such as source line 625) can be referred to as a “column”. A memory element 613m can also include a memory cell 610 that is electrically coupled to a bit line 620m. The bit line 620m can couple the memory element 613 to other memory elements not depicted herein. Memory elements that are electrically connected via a common bit line can be referred to as a “row”. The memory transistor 615m can be electrically connected to a voltage source (not shown) via a word line 630m.

The memory assembly 600 also includes a reference element 603. As discussed above, a reference element can include a reference transistor 605 and a reference component, for example a reference resistor (or reference cell) 600. In embodiments, the reference resistor 600 can be connected to a supply voltage V_{DD}. The supply voltage can provide current to the reference transistor 605 in order to determine the resistance across the reference element 603. The source of the reference transistor 605 is electrically connected to an output 625r. The output 625r can then be electrically connected to the sense amplifier 660 in order to compare the voltage from the memory element to the reference element in order to determine the resistance of the memory element. Commonly utilized architectures and methods of electrically connecting memory elements and reference elements into assemblies and arrays can be utilized herein.

Two or more assemblies, such as that depicted in FIG. 6A can be electrically coupled together to form memory arrays. In embodiments, more than one column, such as that depicted in FIG. 6A can be arranged and individual memory elements within each column can be electrically connected, via bit lines to form a column/row array of memory elements. Generally, in such an embodiment, each column will have a single reference element that can be utilized to determine the resistance of the memory element.

The plurality of memory elements can be arranged in a matrix, or a memory array having bit lines and source lines connecting the plurality of memory elements; also included is a plurality of word lines, wherein each of the plurality of memory transistors are operatively coupled to a word line. An exemplary memory arrays that includes columns of memory elements is depicted in FIG. 6B. FIG. 6B depicts an exemplary memory array that includes a plurality of memory elements 613 as disclosed herein. Generally, a plurality refers to at least two and generally refers to more than two. As seen in FIG. 6B, each of the memory elements includes a memory transistor and a memory cell. The memory elements can be connected in columns, shown as memory elements 613b, 613b+1, and 613b+x, that are included in the dashed box 675 using source line 670. The memory elements can be connected in rows, shown as memory elements 613a+x and 613b+x, that are included in the dashed box 665 using source line 660. Commonly utilized architectures and methods of electrically connecting memory cells into arrays can be utilized herein. The gate of the transistors are connected to word lines 680, by which memory gate voltages are supplied.

Each column, such as column 675 includes an operatively coupled reference element 603b. The reference element 603b is operatively coupled to the column 675 of memory elements so that the resistance from the reference element and the resistance of a memory element within the column 675 can be compared in order to determine the resistance state of the memory element within the column 675.

Methods of determining the resistance state of a non volatile memory cell are also disclosed herein. Determining the resistance state of a non volatile memory cell can also be referred to as reading a memory cell. Generally, such methods include the steps of determining the resistance of the memory element, determining the resistance of the reference element and comparing the two resistances to determine the resistance state of the non volatile memory cell. The method can be undertaken by determining the resistance of the reference element first or determining the resistance of the non volatile memory cell first.

Generally, determining the resistance of either the non volatile memory cell or the reference element can include activating the transistor (of the memory element or reference element) and measuring the voltage across the memory element or reference element. As discussed above, the steps of activating the reference transistor and the memory transistor is accomplished through application of a memory gate voltage and a reference gate voltage respectively. The memory gate voltages and reference gate voltages that are utilized are such that the difference between the voltage across the memory element and the voltage across the reference element is maximized.

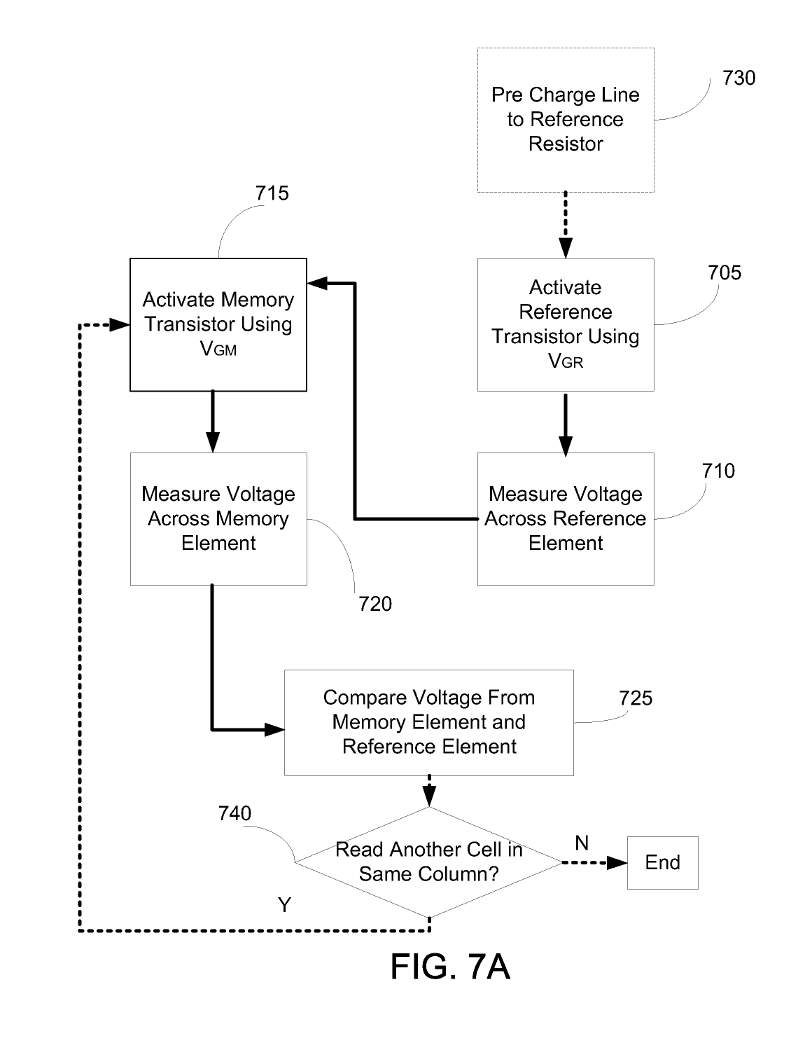

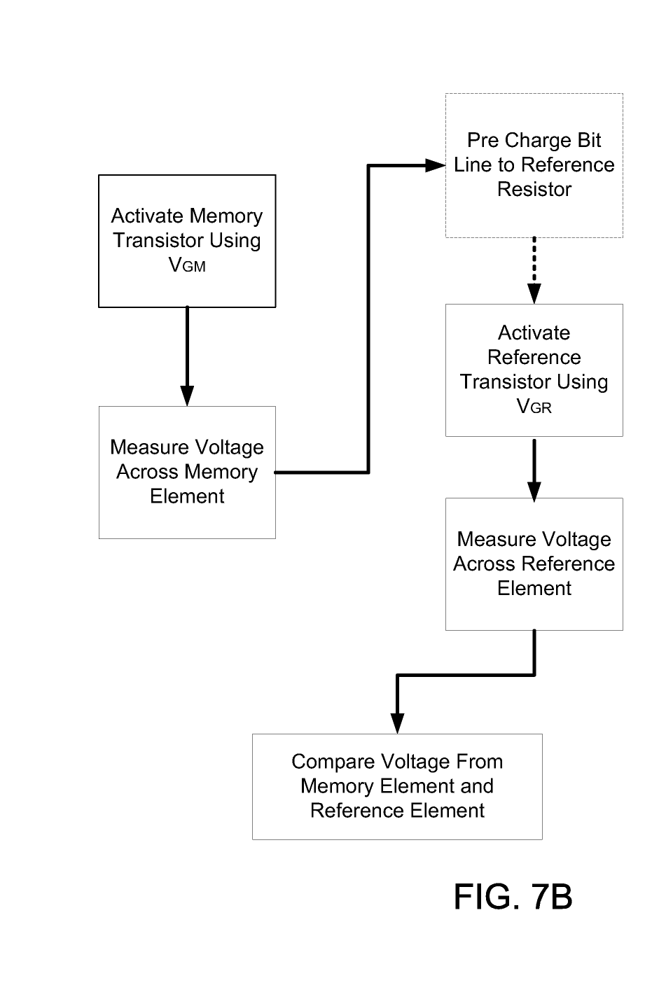

FIG. 7A illustrates steps in an exemplary method disclosed herein. The first step in this exemplary method includes step 705, activating the reference transistor by applying a reference gate voltage V_{GR}. After activation of the transistor, the next step, step 710 is to measure the voltage across the reference element. Steps 705 and 710 can generally be said to accomplish the step of determining the resistance of the reference element. After the resistance of the reference element has been determined, the resistance of the memory element can then be determined, by carrying out step 715, activating the memory transistor by applying a memory gate voltage V_{GM}; and step 720, measuring the voltage across the memory element. After the two voltages have been measured, the next step, step 725 is to compare the voltages of the memory element and the reference element in order to determine the resistance state of the memory cell.

The method in FIG. 7A also portrays an optional step, step 730, precharging the line to the reference resistor. This step, if undertaken can be utilized so that the line to the reference element reaches a stable value. This step, if undertaken, can be carried out during the time other steps (either those discussed herein or steps not discussed herein) are being carried out. Precharging, if undertaken can help to stabilize the voltage across the bit line and source line to a median voltage. This can reduce the time it takes to get to bit line saturation upon starting reading. This can be advantageous when reading STRAM because of the smaller sensing margins than other non volatile memory cells, thereby making the signal stability relatively more important.

FIG. 7A also includes decision block 740. In embodiments where another cell in the same column is to be read, step 715 can be repeated again, i.e., another memory transistor (in the same column as the previous memory cell) can be activated. The voltage across that subsequent memory element can then be measured as seen in step 720. The measured voltage across the present memory cell can then be compared to the voltage across the reference component (step 725) to determine a resistance state of the present memory cell. If the cell to be read is from a different column, or no further cell is to be read, the method can be complete.

FIG. 7B illustrates another exemplary method. The method depicted in FIG. 7B can include the same steps as those depicted in FIG. 7A, but are carried out in a different order. The method depicted in FIG. 7A generally determines the resistance of the memory element before it determines the resistance of the reference element and then compares the two in order to determine the resistance state of the non volatile memory cell.

Thus, embodiments of NON VOLATILE MEMORY HAVING INCREASED SENSING MARGIN are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1. A non volatile memory assembly comprising:
a reference element comprising:
a reference component; and
a reference transistor,
wherein the reference component is electrically connected to the reference transistor, and the reference transistor controls the passage of current across the reference component;
at least one non volatile memory element comprising:
a non volatile memory cell, having at least a low and a high resistance state; and
an output that electrically connects the reference element with the at least one non volatile memory element,
wherein the reference transistor and the memory transistor are activated by a reference gate voltage and a memory gate voltage respectively, and the reference gate voltage and the memory gate voltage are not the same.

2. The non volatile memory assembly according to claim 1, wherein at least one non volatile memory element further comprises a memory transistor, wherein the non volatile memory cell is electrically connected to the memory transistor, and the memory transistor controls the passage of current across the non volatile memory cell.

3. The non volatile memory assembly according to claim 1, wherein the reference component has a resistance that is less than or equal to the high resistance state of the non volatile memory cell and greater than or equal to the low resistance state of the non volatile memory cell.

4. The non volatile memory assembly according to claim 1, wherein the non volatile memory cell is a spin torque transfer random access memory (STRAM) cell.

5. The non volatile memory assembly according to claim 3, wherein the reference component comprises a MTJ stack.

6. The non volatile memory assembly according to claim 1, wherein the memory gate voltage is such that a ratio of the memory gate voltage to the supply voltage of the memory assembly is from about 35% to about 50%.

7. The non volatile memory assembly according to claim 1, wherein the reference gate voltage is such that a ratio of the reference gate voltage to the supply voltage of the memory assembly is from about 50% to about 65%.

8. The non volatile memory assembly according to claim 1, wherein the reference transistor is a p-type metal-oxide-semiconductor field-effect transistor and the memory transistor is a n-type metal-oxide-semiconductor field-effect transistor.

9. The non volatile memory assembly according to claim 1, wherein the reference component comprises a first MTJ stack in a parallel magnetic state and a second MTJ stack in an anti-parallel magnetic state, the first and second MTJ stack being connected in parallel.

10. A non volatile memory array comprising:
at least one reference element comprising:
a reference component; and
a reference transistor,
wherein the reference component is electrically connected to the reference transistor, and the reference transistor controls the passage of current across the reference component; and
a plurality of non volatile memory elements, each non volatile memory element comprising:
a non volatile memory cell, having at least a low and a high resistance state; and
a memory transistor,
wherein the non volatile memory cell is electrically connected to the memory transistor, and the memory transistor controls the passage of current across the non volatile memory cell;
wherein the plurality of non volatile memory cells are arranged in a matrix of rows and columns,
wherein a selected reference element is operatively coupled to a single column of non volatile memory cells, and
wherein a selected reference transistor and a selected memory transistor are activated by a reference gate voltage and a memory gate voltage respectively, and the reference gate voltage and the memory gate voltage are not the same.

11. The non volatile memory array according to claim 10, wherein the columns of non volatile memory cells are coupled via source lines and the rows of non volatile memory cells are coupled via bit lines.

12. The non volatile memory array according to claim 10, wherein the plurality of non volatile memory cells are STRAM cells and the at least one reference component comprises at least one MTJ stack.

13. The non volatile memory array according to claim 8, wherein the reference transistor is a p-type metal-oxide-semiconductor field-effect transistor and the memory transistor is a n-type metal-oxide-semiconductor field-effect transistor.

14. A method of determining the resistance state of a non volatile memory cell comprising the steps of:
providing a non volatile memory element, the non volatile memory element comprising:
a non volatile memory cell, having a high and low resistance state; and
a memory transistor, wherein the transistor can be activated by application of a memory gate voltage;
providing a reference cell, the reference cell comprising:
a reference component; and
a reference transistor, wherein the reference transistor can be activated by application of a reference gate voltage;
activating the memory transistor by application of the memory gate voltage causing a current to pass across the non volatile memory cell;
measuring a voltage across the non volatile memory cell;
activating the reference transistor by application of a reference gate voltage causing a current to pass across the reference component;
measuring a voltage across the reference component; and
comparing the voltage across the non volatile memory cell to the voltage across the reference component to determine a resistance state of the non volatile memory cell,
wherein the memory gate voltage and the reference gate voltage are independently chosen to maximize the difference between the resistance across the non volatile memory cell and the resistance across the reference component.

15. The method according to claim 14, wherein the steps of activating and measuring the voltage across the reference element are undertaken before the steps of activating and measuring the voltage across the non volatile memory element.

16. The method according to claim 14 further comprising precharging the reference transistor before measuring the voltage across the reference component

17. The method according to claim 14, wherein the non volatile memory cell is a STRAM cell.

18. The method according to claim 14, wherein the reference transistor is a p-type metal-oxide-semiconductor field-effect transistor and the memory transistor is a n-type metal-oxide-semiconductor field-effect transistor.

19. The method according to claim 14 further comprising:
activating another memory transistor in the same column as a previous memory transistor;
measuring a voltage across a present non volatile memory cell; and
comparing the voltage across the present non volatile memory cell to the voltage across the reference component to determine a resistance state of the present non volatile memory cell.

20. The method according to claim 14, wherein measuring a voltage across the reference component comprises measuring a voltage across two MTJ stacks connected in parallel, with the first MTJ stack having a parallel magnetic state and the second MTJ stack having an anti-parallel magnetic state.
